(19) United States
(12) Patent Application Publication
(10) Pub. No.: US 2025/0338646 A1
(43) Pub. Date: Oct. 30, 2025

(54) PHOTOELECTRIC CONVERSION DEVICE WITH CHARGE LEAK PORTION

(71) Applicant: CANON KABUSHIKI KAISHA, Tokyo (JP)

(72) Inventors: DAIKI SHIRAHIGE, Kanagawa (JP); SHUHEI HAYASHI, Kanagawa (JP); SHUNICHI WAKASHIMA, Tokyo (JP); HIROSHI SEKINE, Kanagawa (JP); GINJIRO TOYOGUCHI, Tokyo (JP)

(21) Appl. No.: 19/189,988

(22) Filed: Apr. 25, 2025

(30) Foreign Application Priority Data
Apr. 30, 2024 (JP) 2024-074043

(51) Int. Cl. H10F 39/00

(52) U.S. Cl. CPC H10F 39/8033; H10F 39/80373; H10F 39/8063

(57) ABSTRACT

First and second photoelectric converters share microlens. The first photoelectric converter includes first region of first conductivity type and second region of first conductivity type between the first region and surface of substrate and connected to the first region via first connection. The second photoelectric converter includes third region of first conductivity type and fourth region of first conductivity type between the third region and the surface and connected to the third region via second connection. Region of second conductivity type is arranged between the first and second regions and between the third and fourth regions. First isolation region extends between the first and third regions. Second isolation region extends between the second and fourth regions. First pixel includes intersection where the first and second isolation regions intersect, charge leak portion arranged at the intersection.

### BACKGROUND

### Technical Field

The aspect of the embodiments relates to a photoelectric conversion device with a charge leak portion and equipment.

### Description of the Related Art

There is provided a photoelectric conversion device in which a plurality of photoelectric converters are arranged in each pixel for on-imaging plane phase difference auto focus (AF). Japanese Patent Laid-Open No. 2023-27686 describes a photoelectric conversion device including pixels each having a first photoelectric converter and a second photoelectric converter which share a microlens. In the photoelectric conversion device described in Japanese Patent Laid-Open No. 2023-27686, a first layer and a second layer are stacked in a substrate. The first photoelectric converter includes a first impurity region arranged in the first layer and a second impurity region arranged in the second layer, and the second photoelectric converter includes a third impurity region arranged in the first layer and a fourth impurity region arranged in the second layer. In the first layer, a first isolation region is provided between the first impurity region and the third impurity region, and in the second layer, a second isolation region is provided between the second impurity region and the fourth impurity region. The plurality of pixels include a pixel in which the first isolation region and the second isolation region extend in different directions in a planar view with respect to a first surface.

In a configuration in which a plurality of photoelectric converters are arranged to share a microlens, the total number of saturated charges may decrease and gradation reproducibility may lower, as compared to a configuration in which one photoelectric converter is arranged for one microlens.

### SUMMARY

One of aspects of the embodiments provides a conversion device including a substrate on which a plurality of pixels are arranged, each pixel including a first photoelectric converter and a second photoelectric converter that share a microlens, the substrate including a first surface and a second surface arranged between the first surface and the microlens, wherein the first photoelectric converter includes a first region of a first conductivity type arranged between a predetermined depth of the substrate and the second surface, and a second region of the first conductivity type arranged between the predetermined depth and the first surface and electrically connected to the first region via a first connection, the second photoelectric converter includes a third region of the first conductivity type arranged between the second surface and the predetermined depth, and a fourth region of the first conductivity type arranged between the predetermined depth and the first surface and electrically connected to the third region via a second connection, a region of a second conductivity type is arranged between the first region and the second region and between the third region and the fourth region, a first isolation region is arranged to extend between the first region and the third region, and a second isolation region is arranged to extend between the second region and the fourth region, the plurality of pixels include a first pixel including an intersection where the first isolation region and the second isolation region intersect each other in an orthogonal projection to the first surface, and the first pixel includes a charge leak portion arranged at the intersection so as to electrically connect the first photoelectric converter and the second photoelectric converter.

Further features of the present invention will become apparent from the following description of exemplary embodiments with reference to the attached drawings.

### BRIEF DESCRIPTION OF THE DRAWINGS

FIG. 1 is a view showing the configuration of a photoelectric conversion device according to the first embodiment;

FIGS. 2A and 2B are plan views showing examples of the configurations of two types of pixels, respectively;

FIGS. 3A to 3C are views showing three examples of the configuration of the pixel array of the photoelectric conversion device;

FIGS. 4A to 4E are views showing an example of the configuration of a pixel of a first type;

FIGS. 5A to 5E are views showing an example of the configuration of a pixel of a second type;

FIG. 6 is a view exemplifying a method of forming a first isolation region and an implantation concentration profile;

FIGS. 7A to 7C are views for explaining an example of the configuration of each of the pixel of the first type and the pixel of the second type;

FIGS. 8A to 8D are views for explaining an example of the configuration of each of the pixel of the first type and the pixel of the second type;

FIGS. 9A and 9B are views each showing an example of the configuration of a pixel of a photoelectric conversion device according to the second embodiment; and

FIG. 10 is a view for explaining an example of the configuration of equipment.

### DESCRIPTION OF THE EMBODIMENTS

Hereinafter, exemplary embodiments of the disclosure will be described in detail with reference to the accompanying drawings. It should be noted that the following embodiments are not intended to limit the scope of the appended claims. A plurality of features are described in the embodiments, but not all the plurality of features are necessarily essential to the disclosure, and the plurality of features may arbitrarily be combined. Also, in the accompanying drawings, the same reference numerals denote the same or similar parts, and a repetitive description will be omitted.

In each embodiment to be described below, a device for image capturing will mainly be described as an example of a photoelectric conversion device. However, each embodiment is not limited to the device for image capturing, and is applicable to other examples of the photoelectric conversion device. Examples are a distance measurement apparatus (an apparatus for distance measurement using Time Of Flight (TOF) or focus detection), and a photometric apparatus (an apparatus for measuring an incident light amount or the like).

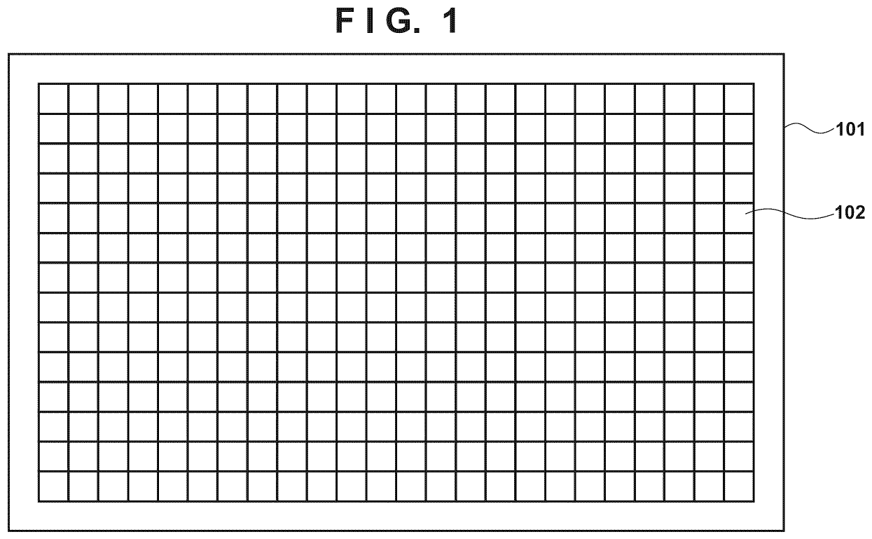

A photoelectric conversion device 101 according to the first embodiment will be described with reference to FIGS. 1 to 8D. The photoelectric conversion device 101 can be formed as, for example, an image capturing device that outputs a digital or analog image signal obtained by capturing an optical image. Alternatively, the photoelectric conversion device 101 may be formed as a processing device that processes information obtained from an optical image and outputs the result. A case where a signal charge is an electron will be described below. The same applies to a case where a signal charge is a hole except that the conductivity type of an impurity is reversed. The following description assumes that the first conductivity type is an n type and the second conductivity type is a p type. However, in a case where the signal charge is a hole, the first conductivity type is a p type and the second conductivity type is an n type.

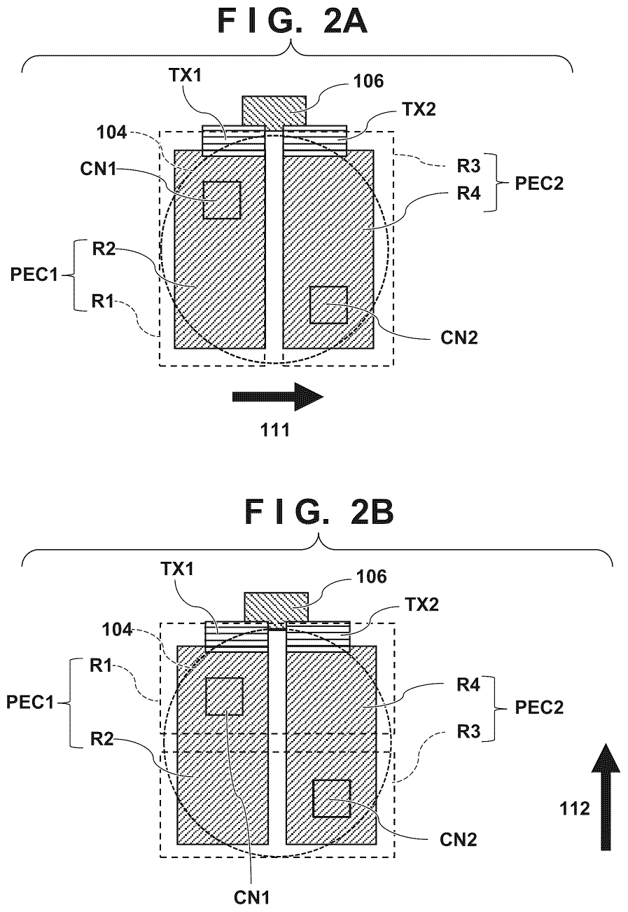

As exemplified in FIG. 1, the photoelectric conversion device 101 includes a plurality of pixels 102. For example, the plurality of pixels 102 can be arranged to form a plurality of rows and a plurality of columns, thereby forming a pixel array. However, the disclosure is not limited to this. FIGS. 2A and 2B are schematic plan views showing the configurations of two types of pixels 102, respectively. FIGS. 2A and 2B each schematically show the configuration when viewing a first surface of a substrate on which the pixels 102 are arrayed. The first surface is normally a surface recognized as an upper surface but may be understood as a surface on which a transistor is arranged or a surface undergoing a lithography step at the time of manufacturing. A second surface as a surface on the opposite side of the first surface is normally a surface recognized as a lower surface, and a microlens 104 can be arranged on the second surface side. The photoelectric conversion device arranged with the microlens on the second surface (lower surface) side is called a back-illuminated type.

Light having entered the photoelectric conversion device 101 passes through the microlens 104, and enters a first photoelectric converter PEC1 and a second photoelectric converter PEC2 formed on the substrate. The first photoelectric converter PEC1 and the second photoelectric converter PEC2 share the one microlens 104. The pixel 102 includes a floating diffusion 106 (to be also referred to as an FD hereinafter). The pixel 102 also includes a first transfer gate TX1 for transferring charges of the first photoelectric converter PECI to the FD 106, and a second transfer gate TX2 for transferring charges of the second photoelectric converter PEC2 to the FD 106.

The first photoelectric converter PEC1 includes a first region R1 of the first conductivity type arranged on the first surface side (between a predetermined depth of the substrate and the first surface) in the substrate, and a second region R2 of the first conductivity type arranged on the second surface side (in other words, between the predetermined depth of the substrate and the second surface) in the substrate. The first region R1 and the second region R2 are electrically connected by a first connection CN1. The second photoelectric converter PEC2 includes a third region R3 of the first conductivity type arranged on the first surface side (between the predetermined depth of the substrate and the first surface) in the substrate, and a fourth region R4 of the first conductivity type arranged on the second surface side (between the predetermined depth of the substrate and the second surface) in the substrate. The third region R3 and the fourth region R4 are electrically connected by a second connection CN2. Referring to FIGS. 2A and 2B, the second region R2 and the fourth region R4 on the first surface side are indicated by solid lines, and the first region RI and the third region R3 on the second surface side are indicated by dotted lines.

Charges (electrons) generated by photoelectric conversion in the first region R1 on the second surface (lower surface) side move to the second region R2 via the first connection CN1, and are transferred to the FD 106 when a potential of an active level is supplied to the first transfer gate TX1. The first region R1 forms a main photoelectric conversion portion, and the second region R2 forms a charge transport portion. Similarly, charges (electrons) generated by photoelectric conversion in the third region R3 on the second surface (lower surface) side move to the fourth region R4 via the second connection CN2, and are transferred to the FD 106 when a potential of an active level is supplied to the second transfer gate TX2. The third region R3 forms a main photoelectric conversion portion, and the fourth region R4 forms a charge transport portion.

For on-imaging plane phase difference AF, a pixel configuration in which the first and second photoelectric converters share one microlens can be adopted. In this pixel configuration, an object pattern for which detection of a defocus amount (in other words, focusing) is easy changes depending on a direction in which the first and second photoelectric converters are arranged. For example, if the first and second photoelectric converters are arranged in the horizontal direction, it is possible to obtain high sensitivity with respect to detection of the defocus amount of an object with a contrast of vertical stripes but it is impossible to obtain high sensitivity with respect to detection of the defocus amount of an object with a contrast of horizontal stripes. In this example, arranging the first and second photoelectric converters in a given direction means arranging the first and second photoelectric converters so that the centers of gravity of the first and second photoelectric converters shift in the direction. The direction (arrangement direction) in which the first and second photoelectric converters each including the main photoelectric conversion portion and the charge transport portion are arranged means a direction in which the main photoelectric conversion portions are arranged. To make it easy to detect the defocus amounts of more object patterns, a plurality of types of pixels that are different in direction in which the photoelectric converters (main photoelectric conversion portions) are arrayed are arranged.

Although not shown in FIG. 1, the photoelectric conversion device 101 can include, for example, a vertical scanning circuit that selects a row of the pixel array, a readout circuit that reads out the signals of the pixels of the pixel array, and a horizontal scanning circuit that sequentially outputs the signals read out by the readout circuit.

FIG. 2A shows a pixel (second pixel) in which the first region R1 and the third region R3 as the main photoelectric conversion portions are arranged in a horizontal direction 111. This arrangement is advantageous in detecting the defocus amount of an object with a contrast of vertical stripes. FIG. 2B shows a pixel (first pixel) in which the first regions R1 and the third region R3 as the main photoelectric conversion portions are arranged in a vertical direction 112. This arrangement is advantageous in detecting the defocus amount of an object with a contrast of horizontal stripes. Note that the expressions “horizontal” and “vertical” are used for the sake of descriptive convenience but are subjective concepts. More objectively, a pixel in which the main photoelectric conversion portions are arranged in a given direction is advantageous in detecting the defocus amount of an object pattern in which light intensity changes in the direction.

In one embodiment a direction in which the second region R2 and the fourth region R4 as the charge transport portions are arranged is the same for the pixel shown in FIG. 2A and the pixel shown in FIG. 2B. This configuration is advantageous for making the positions of the charge transport portions, the transfer gates, and the FD in the pixel the same for the plurality pixels regardless of the direction (arrangement direction) in which the main photoelectric conversion portions are arranged. This is useful to reduce a manufacturing variation between the pixels and reduce a characteristic difference between the pixels.

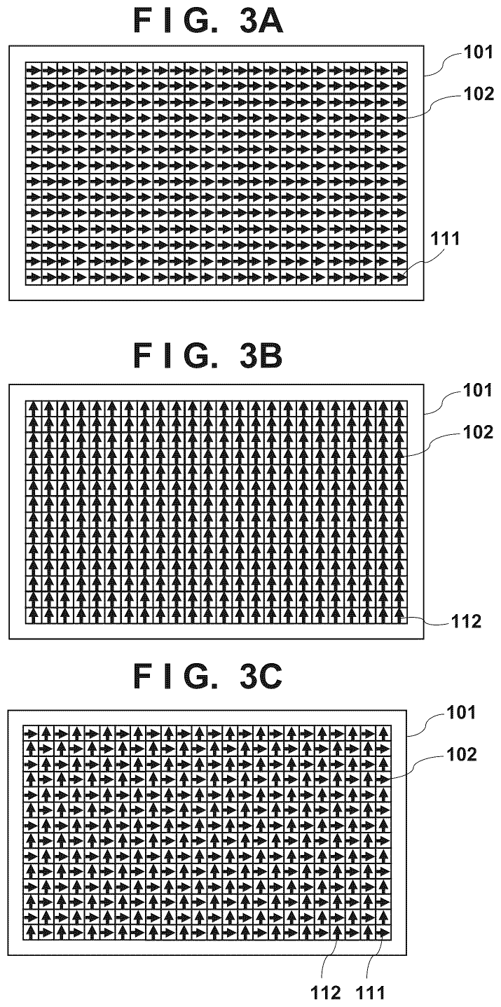

FIGS. 3A to 3C each schematically show an example of the configuration of the pixel array of the photoelectric conversion device 101. In the configuration example shown in FIG. 3A, all the pixels 102 of the photoelectric conversion device 101 are pixels in each of which the main photoelectric conversion portions are arranged in the horizontal direction 111. In the configuration example shown in FIG. 3B, all the pixels 102 of the photoelectric conversion device 101 are pixels in each of which the main photoelectric conversion portions are arranged in the vertical direction 112. In the configuration example shown in FIG. 3C, the photoelectric conversion device 101 includes the plurality of pixels 102 in each of which the main photoelectric conversion portions are arranged in the horizontal direction 111 and the plurality of pixels 102 in each of which the main photoelectric conversion portions are arranged in the vertical direction 112.

The photoelectric conversion device 101 shown in FIG. 3A is advantageous in performing, at high speed with high accuracy, AF processing for a vertical stripe object pattern, and the photoelectric conversion device 101 shown in FIG. 3B is advantageous in performing, at high speed with high accuracy, AF processing for a horizontal stripe object pattern. The photoelectric conversion device 101 shown in FIG. 3C is advantageous in performing, at high speed with high accuracy, AF processing for both a vertical stripe object pattern and a horizontal stripe object pattern. The photoelectric conversion device 101 shown in FIG. 3C includes two types of pixels with respect to the direction in which the main photoelectric conversion portions are arranged but may include more types of pixels. Another type of pixel to be added is a pixel in which the main photoelectric conversion portions are arranged in an oblique direction.

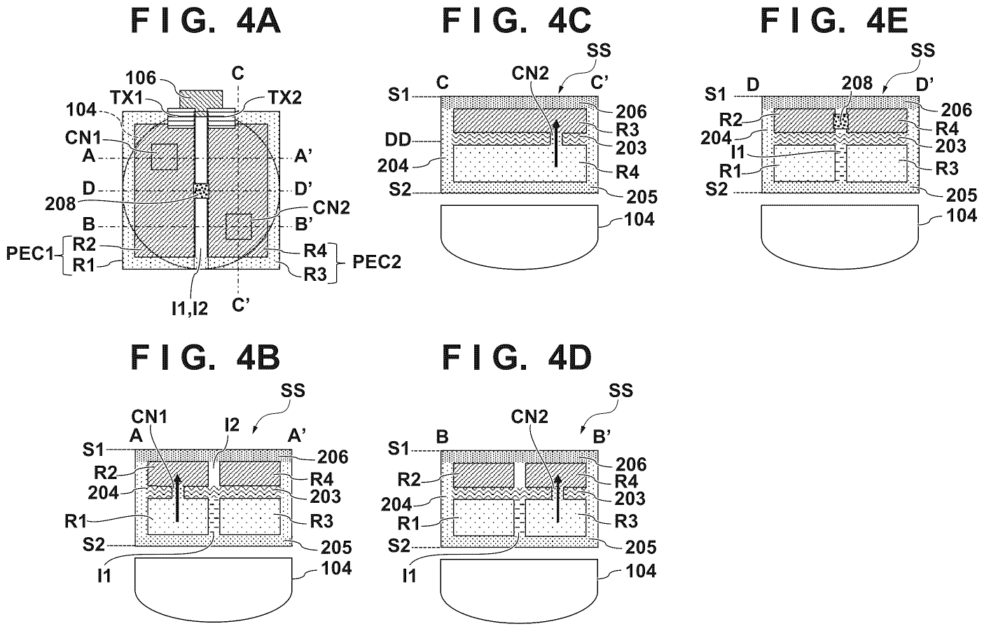

FIGS. 4A to 4E show an example of the more detailed configuration of the pixel 102 (second pixel) of the first type shown in FIG. 2A. FIG. 4A is a schematic plan view showing the configuration of the pixel 102 of the first type. FIG. 4B is a schematic sectional view taken along a line A-A′ shown in FIG. 4A. FIG. 4C is a schematic sectional view taken along a line C-C′ shown in FIG. 4A. FIG. 4D is a schematic sectional view taken along a line B-B′ shown in FIG. 4A. FIG. 4E is a schematic sectional view taken along a line D-D′ shown in FIG. 4A.

A substrate SS on which the pixels 102 are arranged includes a first surface S1 and a second surface S2. The second surface S2 is arranged between the first surface S1 and the microlens 104. In other words, the microlens 104 is arranged on the side of the second surface S2 (lower surface) of the substrate SS. The substrate SS can be, for example, a single-crystal silicon substrate.

The first photoelectric converter PECI includes the first region RI of the first conductivity type arranged between a predetermined depth DD of the substrate SS and the second surface S2, and the second region R2 of the first conductivity type arranged between the predetermined depth DD and the first surface S1. Note that the predetermined depth DD can be decided in accordance with required specifications. The second region R2 is electrically connected to the first region R1 via the first connection CN1. The second photoelectric converter PEC2 includes the third region R3 of the first conductivity type arranged between the second surface S2 and the predetermined depth DD, and the fourth region R4 arranged between the predetermined depth DD and the first surface S1. The fourth region R4 is electrically connected to the third region R3 via the second connection CN2.

A region 203 of the second conductivity type is arranged between the first region R1 and the second region R2 and between the third region R3 and the fourth region R4. The first connection CN1 and the second connection CN2 can be arranged to extend through the region 203 of the second conductivity type. The first connection CN1 and the second connection CN2 can be regions of the first conductivity type.

A first isolation region I1 is arranged to extend between the first region R1 and the third region R3, and a second isolation region I2 is arranged to extend between the second region R2 and the fourth region R4. At this time, the first isolation region I1 may have an elongated shape, and the longitudinal direction of the first isolation region I1 may be a direction orthogonal to the direction in which the first region R1 and the third region R3 are arranged. The second isolation region I2 may have an elongated shape, and the longitudinal direction of the second isolation region I2 may be a direction orthogonal to the direction in which the second region R2 and the fourth region R4 are arranged. In the pixel 102 of the first type, the extending direction of the first isolation region I1 and the extending direction of the second isolation region I2 are parallel to each other. The pixel 102 of the first type can be called a parallel pixel for the sake of convenience.

Light having passed through a first region of a pupil surface of an imaging lens enters the microlens 104 of each pixel 102 of the photoelectric conversion device 101, and passes through the microlens 104 to enter the first region R1. Thus, a charge pair, that is, a hole and an electron are generated by photoelectric conversion in the first region R1, and the electron as a signal charge moves from the first region R1 to the second region R2 via the first connection CN1 along a potential gradient, and is accumulated in the second region R2. Similarly, light having passed through a second region of the pupil surface of the imaging lens enters the microlens 104 of each pixel 102 of the photoelectric conversion device 101, and passes through the microlens 104 to enter the third region R3. Thus, a charge pair, that is, a hole and an electron are generated by photoelectric conversion in the third region R3, and the electron as a signal charge moves from the third region R3 to the fourth region R4 via the second connection CN2 along a potential gradient, and is accumulated in the fourth region R4.

An isolation region 204 of the second conductivity type can be arranged between the adjacent pixels 102 for the purpose of suppressing charge crosstalk between the pixels. In addition, a region 206 of the second conductivity type may be provided between the first surface S1 and the second region R2 and between the first surface S1 and the fourth region R4 for the purpose of suppressing a dark current. Similarly, a region 205 of the second conductivity type may be provided between the second surface S2 and the first region R1 and between the second surface S2 and the third region R3 for the purpose of suppressing a dark current. The first photoelectric converter PEC1 and the second photoelectric converter PEC2 can electrically be isolated by the above-described first isolation region I1 and second isolation region I2. The first isolation region I1 can include a region of the second conductivity type. Alternatively, the first isolation region I1 may include an insulator. Alternatively, the first isolation region I1 may include a region of the second conductivity type and an insulator. The second isolation region I2 can include a region of the second conductivity type. Alternatively, the second isolation region I2 may include an insulator. Alternatively, the second isolation region I2 may include a region of the second conductivity type and an insulator.

For phase difference detection for on-imaging plane phase difference AF, an output (A) of the first photoelectric converter PEC1 and an output (B) of the second photoelectric converter PEC2 of each pixel 102 can be used. The photoelectric conversion device 101 may output (a) A and B, (b) A and A+B, or (c) B and A+B. In the case of (b), B can be obtained by calculating the difference between (A+B) and A. In the case of (c), A can be obtained by calculating the difference between (A+B) and B. A+B is used to generate an image signal (image data).

When capturing a high-luminance object, the first photoelectric converter PEC1 (or second photoelectric converter PEC2) can generate signal charges exceeding a charge amount that can be accumulated. In this case, by causing the charges to leak from the first photoelectric converter PEC1 (or second photoelectric converter PEC2) to the second photoelectric converter PEC2 (or first photoelectric converter PEC1), it is possible to improve the linearity of the output value of the pixel 102 with respect to the luminance of incident light. Thus, the pixel 102 can include a charge leak portion 208 arranged to electrically connect the first photoelectric converter PEC1 and the second photoelectric converter PEC2. Note that the charge leak portion 208 is configured to impede free movement of the charges between the first photoelectric converter PECI and the second photoelectric converter PEC2. More specifically, the charge leak portion 208 forms a potential barrier to some extent with respect to movement of the charges between the first photoelectric converter PEC1 and the second photoelectric converter PEC2. However, if the potential barrier is too high, the charges excessively generated in the first photoelectric converter PEC1 or the second photoelectric converter PEC2 can flow into the FD 106 or another pixel 102. Thus, color reproducibility of the captured image and the like may degrade. Therefore, the height of the potential barrier can be adjusted to satisfy the target specifications.

The charge leak portion 208 is arranged to cross the second isolation region I2. From another viewpoint, the charge leak portion 208 can be arranged between the second region R2 and the fourth region R4. The charge leak portion 208 can include a region of the first conductivity type. The photoelectric conversion device 101 can be formed so that the amount (absolute amount) of an impurity of the second conductivity type in the charge leak portion 208 is smaller than the amount (absolute amount) of an impurity of the second conductivity type in the second isolation region I2. For example, in a step of implanting an impurity of the second conductivity type in the substrate SS to form the second isolation region I2, implantation of the impurity of the second conductivity type in a region to be the charge leak portion 208 can be limited by a mask.

According to one aspect, the charge leak portion 208 can be located between the first surface S1 and the predetermined depth DD. According to another aspect, the shortest distance between the first surface S1 and the charge leak portion 208 may be smaller than the shortest distance between the second surface S2 and the charge leak portion 208. As exemplified in FIGS. 4A to 4E, in an orthogonal projection (or plan view) to the first surface S1, the center (or vertex) of the microlens 104 can be located in the region of the charge leak portion 208.

In one embodiment, the configuration in which the charge leak portion 208 is arranged between the second region R2 and the fourth region R4 is beneficial in obtaining a structure in which excessive charges leak between the first photoelectric converter PEC1 and the second photoelectric converter PEC2 when capturing a high-luminance object. With this configuration, the first photoelectric converter PEC1 and the second photoelectric converter PEC2 are isolated from each other to implement the phase difference detection function, and it is possible to improve the linearity of the output value with respect to the luminance of incident light for each pixel 102.

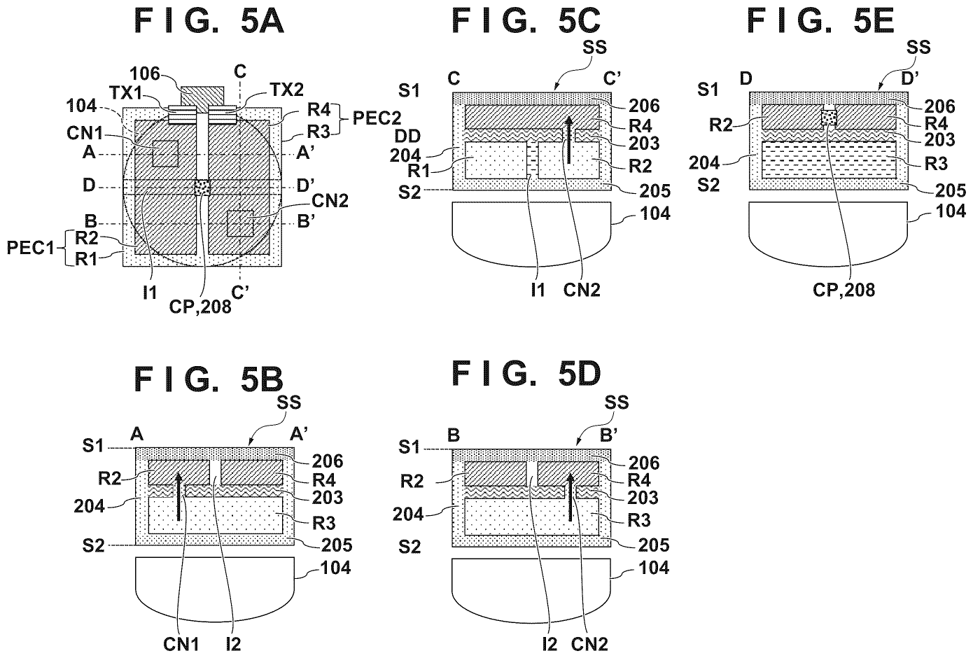

FIGS. 5A to 5E show an example of the more detailed configuration of the pixel 102 (first pixel) of the second type shown in FIG. 2A. FIG. 5A is a schematic plan view showing the configuration of the pixel 102 of the second type. FIG. 5B is a schematic sectional view taken along a line A-A′ shown in FIG. 5A. FIG. 5C is a schematic sectional view taken along a line C-C′ shown in FIG. 5A. FIG. 5D is a schematic sectional view taken along a line B-B′ shown in FIG. 5A. FIG. 5E is a schematic sectional view taken along a line D-D′ shown in FIG. 5A.

The difference of the pixel 102 of the second type from the pixel 102 of the first type will be described below. Matters not mentioned for the pixel 102 of the second type can comply with the description of the pixel 102 of the first type. The pixel 102 of the second type includes an intersection CP where the first isolation region I1 and the second isolation region I2 intersect each other in the orthogonal projection (plan view) to the first surface S1. The pixel 102 of the second type can be called an intersecting pixel for the sake of convenience. The pixel 102 of the second type includes the charge leak portion 208 arranged at the intersection CP so as to electrically connect the first photoelectric converter PEC1 and the second photoelectric converter PEC2. In an example, in the pixel 102 of the second type, the extending direction (in FIG. 5A, the horizontal direction) of the first isolation region I1 and the extending direction (in FIG. 5A, the vertical direction) of the second isolation region I2 are orthogonal to each other. The charge leak portion 208 can be arranged to cross the second isolation region I2. The charge leak portion 208 can be arranged between the second region R2 and the fourth region R4.

The charge leak portion 208 can include a region of the first conductivity type. The photoelectric conversion device 101 can be formed so that the amount (absolute amount) of an impurity of the second conductivity type in the charge leak portion 208 is smaller than the amount (absolute amount) of an impurity of the second conductivity type in the second isolation region I2. For example, in a step of implanting an impurity of the second conductivity type in the substrate SS to form the second isolation region I2, implantation of the impurity of the second conductivity type in a region to be the charge leak portion 208 can be limited by a mask. The photoelectric conversion device 101 typically includes the plurality of pixels 102 of the second type, and the relative position of the charge leak portion 208 in the pixel 102 of the second type can be the same for the plurality of pixels of the second type.

According to one aspect, the charge leak portion 208 can be located between the first surface S1 and the predetermined depth DD. According to another aspect, the shortest distance between the first surface S1 and the charge leak portion 208 may be smaller than the shortest distance between the second surface S2 and the charge leak portion 208. As exemplified in FIGS. 5A to 5E, in the orthogonal projection (or plan view) to the first surface S1, the center (or vertex) of the microlens 104 can be located in the region of the charge leak portion 208.

The pixel 102 of the first type exemplified in FIGS. 4A to 4E and the pixel 102 of the second type exemplified in FIGS. 5A to 5E are different in terms of the direction in which the first region R1 and the second region R2 are arranged. From another viewpoint, the pixel 102 of the first type exemplified in FIGS. 4A to 4E and the pixel 102 of the second type exemplified in FIGS. 5A to 5E are different in terms of the extending direction of the first region R1 and the second region R2 (from another viewpoint, the extending direction of the first isolation region I1). On the other hand, the pixel 102 of the first type exemplified in FIGS. 4A to 4E and the pixel 102 of the second type exemplified in FIGS. 5A to 5E are the same in terms of the direction in which the third region R3 and the fourth region R4 are arranged. From another viewpoint, the pixel 102 of the first type exemplified in FIGS. 4A to 4E and the pixel 102 of the second type exemplified in FIGS. 5A to 5E are the same in terms of the extending direction of the third region R3 and the fourth region R4 (from another viewpoint, the extending direction of the second isolation region I2).

In the pixel 102 of the first type exemplified in FIGS. 4A to 4E, the direction in which the first region R1 and the second region R2 are arranged is the horizontal direction, and it is thus possible to obtain high sensitivity with respect to detection of the defocus amount of an object with a contrast of vertical stripes. On the other hand, in the pixel 102 of the second type exemplified in FIGS. 5A to 5E, the direction in which the first region R1 and the second region R2 are arranged is the vertical direction, and it is thus possible to obtain high sensitivity with respect to detection of the defocus amount of an object with a contrast of horizontal stripes.

In one embodiment, the relative position of the first connection CN1 in the pixel 102 is the same for the pixel 102 of the first type and the pixel 102 of the second type. Furthermore, the relative position of the second connection CN2 in the pixel 102 is the same for the pixel 102 of the first type and the pixel 102 of the second type. This is advantageous in reducing a manufacturing variation between the pixel 102 of the first type and the pixel 102 of the second type and reducing a characteristic difference between the pixel 102 of the first type and the pixel 102 of the second type. In the orthogonal projection (or plan view) to the first surface S1, the charge leak portion 208 can be arranged between the first connection CN1 and the second connection CN2.

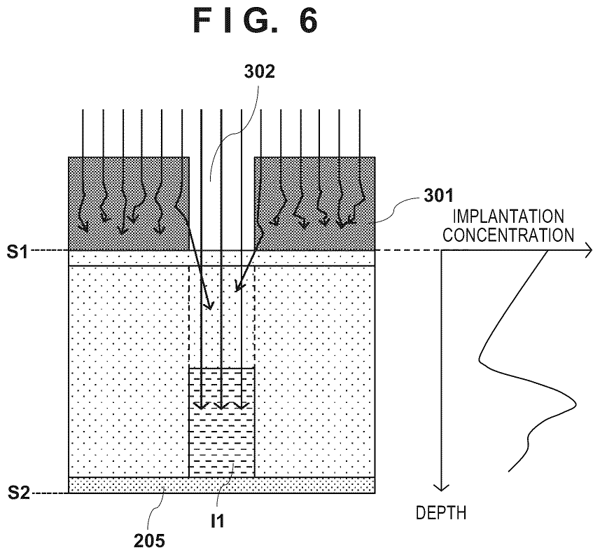

FIG. 6 exemplifies a method of forming the first isolation region I1 and an implantation concentration profile (impurity profile). As described above, the first isolation region I1 is provided to isolate the first region R1 of the first photoelectric converter PEC1 and the third region R3 of the second photoelectric converter PEC2. The first isolation region I1 can be formed by forming a resist pattern 301 on the first surface S1 of the substrate SS and implanting an impurity of the second conductivity type (p type) in the substrate SS via an opening 302 of the resist pattern 301. The impurity of the second conductivity type implanted in the substrate SS via the opening 302 of the resist pattern 301 reaches a deep position in the substrate SS, thereby forming the first isolation region I1. On the other hand, the impurity of the second conductivity type implanted in the resist pattern 301 is ideally, completely absorbed by the resist pattern 301 not to reach the substrate SS. However, a part of the impurity of the second conductivity type implanted near the opening 302 of the resist pattern 301 turns its direction by colliding with a material constituting the resist pattern 301, projects from the side surface of the opening 302, and reaches the substrate SS. Since such impurity consumes energy when passing through the resist pattern 301, it can be implanted at a shallow position in the substrate SS. As shown in a graph on the right side in FIG. 6, the closer to the first surface S1 of the substrate SS, the higher the concentration of the impurity of the second conductivity type implanted in the substrate SS. Thus, the potential profile in the substrate SS can be influenced. More specifically, a potential is low in a region overlapping the first isolation region I1 in the orthogonal projection (or plan view) to the first surface S1, thereby acting on the signal charge (electron) as a potential barrier.

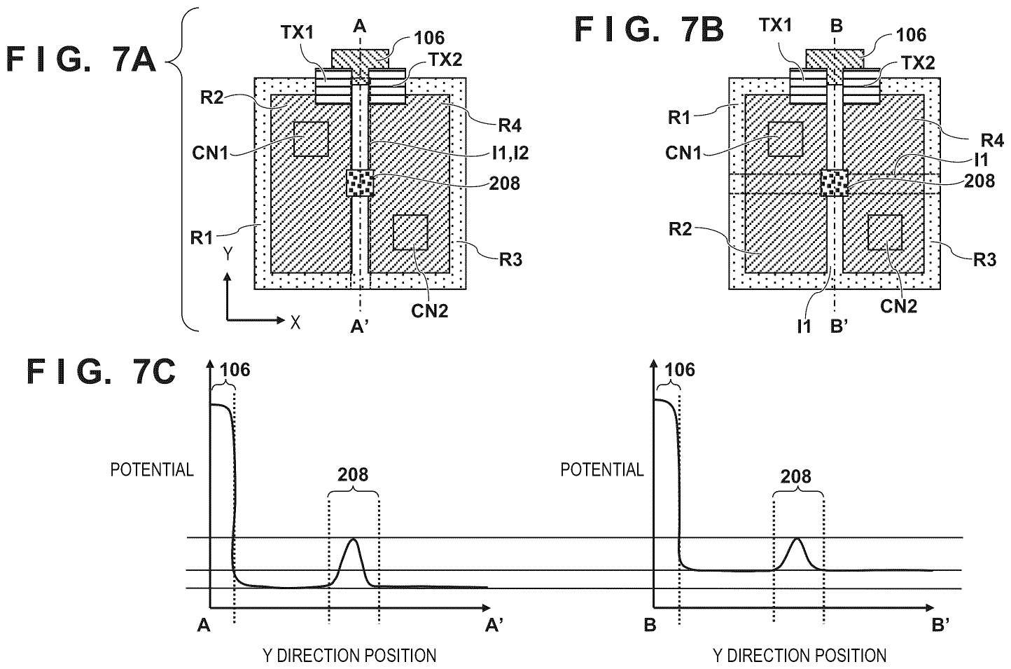

FIG. 7A is a plan view of the pixel 102 of the first type. FIG. 7B is a plan view of the pixel 102 of the second type. On the left side in FIG. 7C, the potential profile of the pixel 102 of the first type along the Y direction of FIG. 7A in the depth of the charge leak portion 208 is exemplified. On the right side in FIG. 7C, the potential profile of the pixel 102 of the second type along the Y direction of FIG. 7B in the depth of the charge leak portion 208 is exemplified. In the two potential profiles shown in FIG. 7C, the ordinate represents the potential and the abscissa represents the position in the Y direction. By providing the charge leak portion 208, the potential barrier for the signal charge (electron) lowers.

The pixel 102 of the first type and the pixel 102 of the second type are different in the extending direction of the first isolation region I1. Therefore, the potential profile on the side (for example, the region between the first surface S1 and the predetermined depth DD) of the first surface S1 in the substrate SS can be different between the pixel 102 of the first type and the pixel 102 of the second type. To cope with this, in one embodiment, the charge leak portion 208 is arranged at the intersection CP of the pixel 102 of the second type and the relative position of the intersection CP (charge leak portion 208) in the pixel 102 of the second type is made identical to the relative position of the charge leak portion 208 in the pixel 102 of the first type. This can make the impurity concentration of the first conductivity type (from another viewpoint, the potential) in the charge leak portion 208 of the pixel 102 of the first type equal to the impurity concentration of the first conductivity type (from another viewpoint, the potential) in the charge leak portion 208 of the pixel 102 of the second type.

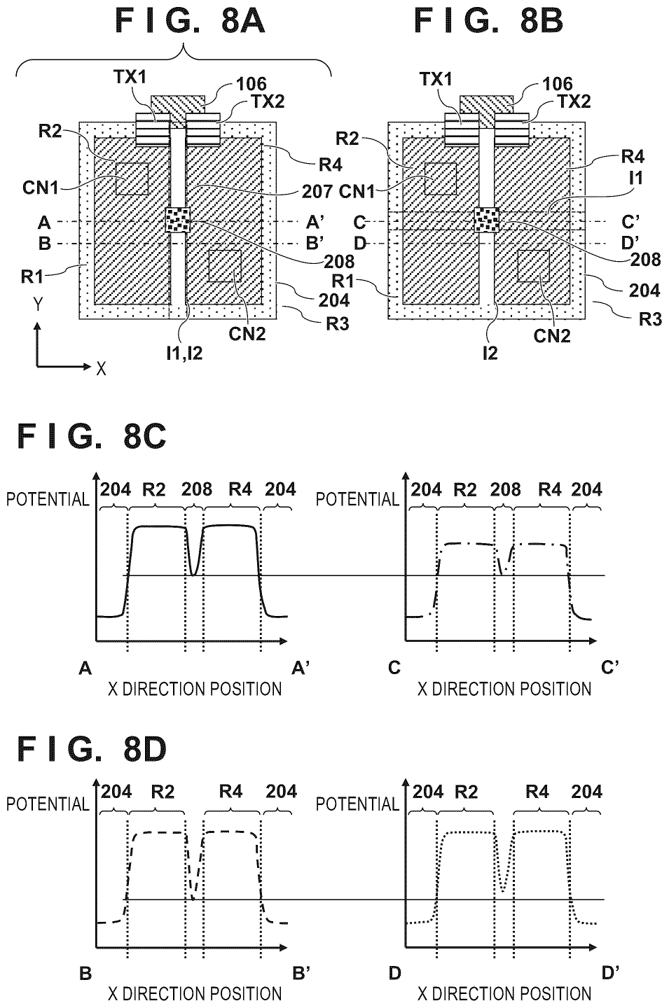

FIG. 8A is a plan view of the pixel 102 of the first type. FIG. 8B is a plan view of the pixel 102 of the second type. On the left side in FIG. 8C, the potential profile of the pixel 102 of the first type along a line A-A′ shown in FIG. 8A in the depth of the charge leak portion 208 is exemplified. On the right side in FIG. 8C, the potential profile of the pixel 102 of the second type along a line C-C′ shown in FIG. 8B in the depth of the charge leak portion 208 is exemplified. On the left side in FIG. 8D, the potential profile of the pixel 102 of the first type along a line B-B′ shown in FIG. 8A in the depth of the charge leak portion 208 is exemplified. On the right side in FIG. 8D, the potential profile of the pixel 102 of the second type along a line D-D′ shown in FIG. 8B in the depth of the charge leak portion 208 is exemplified. In the four potential profiles shown in FIGS. 8C and 8D, the ordinate represents the potential and the abscissa represents the position in the Y direction.

When the potential of the second region R2 reaches the potential of the charge leak portion 208, charges generated by photoelectric conversion and accumulated in the second region R2 leak to the fourth region R4. Similarly, when the potential of the fourth region R4 reaches the potential of the charge leak portion 208, charges generated by photoelectric conversion and accumulated in the fourth region R4 leak to the second region R2.

When comparing the potential profile along the line B-B′ with the potential profile along the line D-D′, there is a difference in potential in the second isolation region I2 due to the impurity of the second conductivity type implanted in the region between the first isolation region I1 and the first surface S1. However, when comparing the potential profile along the line A-A′ with the potential profile along the line C-C′, the potential in the charge leak portion 208 is the same.

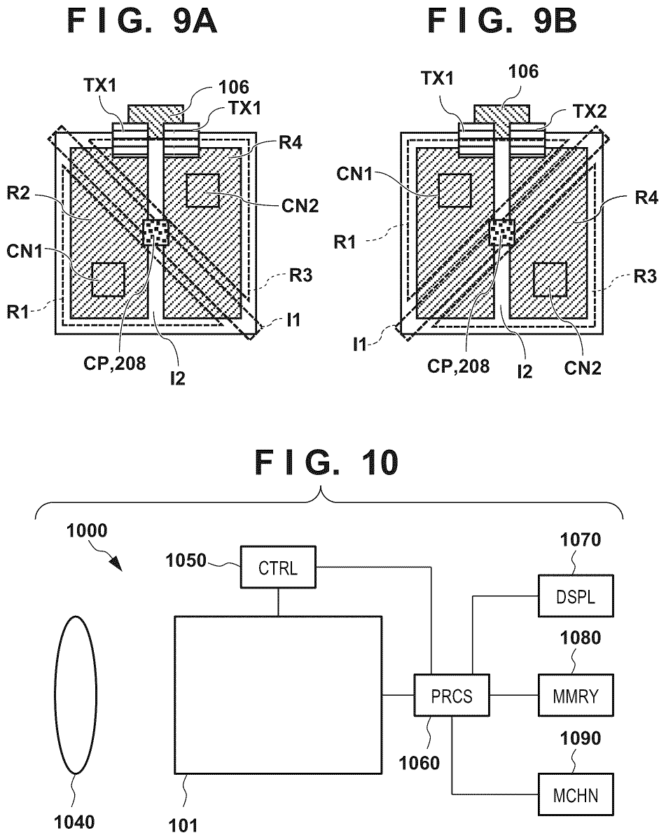

A photoelectric conversion device 101 according to the second embodiment will be described below with reference to FIGS. 9A and 9B. The photoelectric conversion device 101 according to the second embodiment is a modification of the photoelectric conversion device 101 of the first embodiment, and matters not mentioned here comply with the first embodiment. FIG. 9A is a plan view of the first configuration example of a pixel 102 of the second type. FIG. 9B is a plan view of the second configuration example of the pixel 102 of the second type. In the first configuration example and the second configuration example, a second isolation region I2 extends in an oblique direction. In other words, an angle formed by the extending direction of a first isolation region I1 and the extending direction of the second isolation region I2 is larger than 0° and smaller than 90°. Alternatively, the angle formed by the extending direction of the first isolation region I1 and the extending direction of the second isolation region I2 is larger than 90° and smaller than 180°. A plurality of pixels of the photoelectric conversion device 101 include the pixel 102 in the first configuration example and the pixel 102 in the second configuration example. The plurality of pixels of the photoelectric conversion device 101 can further include the pixel 102 of the first type and/or the pixel 102 of the second type according to the first embodiment.

This configuration is advantageous in detecting the defocus amount of a pattern in which light intensity changes in the oblique direction in addition to a vertical stripe pattern and a horizontal stripe pattern.

Equipment 1000 incorporating the photoelectric conversion device 101 will be described below with reference to FIG. 10. The equipment 1000 can include at least one of an optical device 1040, a control device 1050, a processing device 1060, a display device 1070, a storage device 1080, and a mechanical device 1090. The optical device 1040 is implemented by, for example, a lens, a shutter, and a mirror. The control device 1050 controls a semiconductor chip 210. The control device 1050 is, for example, a semiconductor device such as an ASIC.

The processing device 1060 processes a signal output from the photoelectric conversion device 101. The processing device 1060 is a semiconductor device such as a CPU or an ASIC for forming an Analog Front End (AFE) or a Digital Front End (DFE). The display device 1070 is an EL display device or a liquid crystal display device that displays information (image) obtained by the semiconductor chip 210. The storage device 1080 is a magnetic device or a semiconductor device that stores the information (image) obtained by the semiconductor chip 210. The storage device 1080 is a volatile memory such as an SRAM or a DRAM, or a nonvolatile memory such as a flash memory or a hard disk drive.

The mechanical device 1090 includes a moving or propulsion unit such as a motor or an engine. In the equipment 1000, the signal output from the semiconductor chip 210 is displayed on the display device 1070 or transmitted to an external device by a communication device (not shown) included in the equipment 1000. Hence, the equipment 1000 may further include the storage device 1080 and the processing device 1060 in addition to the memory circuits and arithmetic circuits included in the semiconductor chip 210. The mechanical device 1090 may be controlled based on the signal output from the semiconductor chip 210.

In addition, the equipment 1000 is suitable for electronic equipment such as an information terminal (for example, a smartphone or a wearable terminal) which has a shooting function or a camera (for example, an interchangeable lens camera, a compact camera, a video camera, or a monitoring camera). The mechanical device 1090 in the camera can drive the components of the optical device 1040 in order to perform zooming, an in-focus operation, and a shutter operation. Alternatively, the mechanical device 1090 in the camera can move the semiconductor chip 210 in order to perform an anti-vibration operation.

Furthermore, the equipment 1000 can be transportation equipment such as a vehicle, a ship, or an airplane. The mechanical device 1090 in the transportation equipment can be used as a moving device. The equipment 1000 as the transportation equipment is suitable for equipment that transports the semiconductor chip 210 or equipment that uses a shooting function to assist and/or automate driving (steering). The processing device 1060 for assisting and/or automating driving (steering) can perform, based on the information obtained by the semiconductor chip 210, processing for operating the mechanical device 1090 as a moving device. Alternatively, the equipment 1000 may be medical equipment such as an endoscope, measurement equipment such as a distance measurement sensor, analysis equipment such as an electron microscope, office equipment such as a copy machine, or industrial equipment such as a robot.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-074043, filed Apr. 30, 2024, which is hereby incorporated by reference herein in its entirety.

What is claimed is:

1. A photoelectric conversion device including a substrate on which a plurality of pixels are arranged, each pixel including a first photoelectric converter and a second photoelectric converter that share a microlens, the substrate including a first surface and a second surface arranged between the first surface and the microlens, wherein
the first photoelectric converter includes a first region of a first conductivity type arranged between a predetermined depth of the substrate and the second surface, and a second region of the first conductivity type arranged between the predetermined depth and the first surface and electrically connected to the first region via a first connection,
the second photoelectric converter includes a third region of the first conductivity type arranged between the second surface and the predetermined depth, and a fourth region of the first conductivity type arranged between the predetermined depth and the first surface and electrically connected to the third region via a second connection,
a region of a second conductivity type is arranged between the first region and the second region and between the third region and the fourth region,
a first isolation region is arranged to extend between the first region and the third region, and a second isolation region is arranged to extend between the second region and the fourth region,
the plurality of pixels include a first pixel including an intersection where the first isolation region and the second isolation region intersect each other in an orthogonal projection to the first surface, and
the first pixel includes a charge leak portion arranged at the intersection so as to electrically connect the first photoelectric converter and the second photoelectric converter.

2. The device according to claim 1, wherein the charge leak portion is arranged to cross the second isolation region.

3. The device according to claim 1, wherein the charge leak portion is arranged between the second region and the fourth region.

4. The device according to claim 1, wherein the charge leak portion includes a region of the first conductivity type.

5. The device according to claim 1, wherein the second isolation region includes a region of the second conductivity type.

6. The device according to claim 5, wherein an amount of an impurity of the second conductivity type in the charge leak portion is smaller than an amount of an impurity of the second conductivity type in the second isolation region.

7. The device according to claim 1, wherein the charge leak portion is located between the first surface and the predetermined depth.

8. The device according to claim 1, wherein a shortest distance between the first surface and the charge leak portion is smaller than a shortest distance between the second surface and the charge leak portion.

9. The device according to claim 1, wherein in the orthogonal projection, a center of the microlens is located in a region of the charge leak portion.

10. The device according to claim 1, wherein in the orthogonal projection, the charge leak portion is arranged between the first connection and the second connection.

11. The device according to claim 1, wherein the second isolation region includes an insulator.

12. The device according to claim 1, wherein an extending direction of the first isolation region and an extending direction of the second isolation region are orthogonal to each other.

13. The device according to claim 1, wherein the plurality of pixels include a second pixel in which an extending direction of the first isolation region and an extending direction of the second isolation region are parallel to each other.

14. The device according to claim 1, wherein
the plurality of pixels include a plurality of first pixels, and
a relative position of the charge leak portion in the first pixel is the same for the plurality of first pixels.

15. The device according to claim 1, wherein each pixel further includes a floating diffusion, a first transfer gate configured to transfer a charge of the first photoelectric converter to the floating diffusion, and a second transfer gate configured to transfer a charge of the second photoelectric converter to the floating diffusion.

16. Equipment comprising:
a photoelectric conversion device defined in claim 1, and
a processing device configured to process a signal output from the photoelectric conversion device.
